(19) United States
(12) Patent Application Publication
(10) Pub. No.: US 2006/0001170 A1
(43) Pub. Date: Jan. 5, 2006

(54) Conductive compound cap layer

(76) Inventors: Fan Zhang, Singapore (SG); Tae Jong Lee, Singapore (SG); Liang choo Hsia, Singapore (SG)

Correspondence Address: WILLIAM STOFFEL, PMB 455, 1735 MARKET ST. - STE. A, PHILADELPHIA, PA, 19103-7502, US

(21) Appl. No.: 10/882,855

(22) Filed: Jul. 1, 2004

(51) Int. Cl. H01L 29/40; H01L 21/44

(52) U.S. Cl. 257/762; 438/687; 438/612; 257/782

(57) ABSTRACT

An interconnect structure and method thereof comprising: a interconnect and a compound cap layer. The interconnect has a compound cap layer thereover. The interconnect is preferably comprised of copper. The compound cap layer is preferably comprised of a copper-metal (Cu-Me) compound or a metal; and is more preferably comprised of a Cu—Sn compound or Ni metal. A dielectric cap layer is formed over the compound cap layer. The compound cap layer can provide a barrier capping effect to the Cu to minimize the out-diffusion of Cu and therefore improve the electro-migration performance of Cu. The compound cap layer has excellent adhesion to dielectric cap layers, especially SiN and SiC dielectric cap layers.

### BACKGROUND OF THE INVENTION

1) Field of the Invention

This invention relates generally to a device and the fabrication of a semiconductor device and more particularly to a device and a method of manufacturing a semiconductor device having copper interconnects.

2) Description of the Prior Art

Copper (Cu) and Cu alloys have received considerable attention as a candidate for replacing Al in VLSI interconnect metallization. Cu has a lower resistivity than Al. In addition, Cu has improved electrical properties vis-a-vis W, making Cu a desirable metal for use as a conductive plug as well as conductive wiring.

Electroless plating and electroplating of Cu and Cu alloys offer the prospect of low cost, high throughput, high quality plated films and efficient via contact/via hole and trench filling capabilities. Electroless plating generally involves the controlled autocatalytic deposition of a continuous film on the catalytic surface by the interaction in solution of a metal salt and a chemical reducing agent. Electroplating comprises the electrodeposition of an adherent metallic coating on an electrode employing externally supplied electrons to reduce metal ions in the plating solution. A seed layer is required to catalyze electroless deposition or to carry electrical current for electroplating. For electroplating, the seed layer must be continuous. For electroless plating, very thin catalytic layers, e.g., less than 100 Angstroms, can be employed in the form of islets of catalytic metal.

There are disadvantages attendant upon the use of Cu or Cu alloys. For example, Cu readily diffuses through silicon dioxide, the typical dielectric interlayer material employed in the manufacture of semiconductor devices, into silicon elements and adversely affects device performance.

One approach to forming Cu plugs and wiring comprises the use of damascene structures employing CMP. However, due to Cu diffusion through dielectric interlayer materials, such as silicon dioxide, Cu interconnect structures must be encapsulated by a diffusion barrier layer. Typical diffusion barrier metals include tantalum (Ta), tantalum nitride (TaN), titanium nitride (TiN), titanium-tungsten (TiW), and silicon nitride (Si3N4) for encapsulating Cu. The use of such barrier materials to encapsulate Cu is not limited to the interface between Cu and the dielectric interlayer, but includes interfaces with other metals as well.

Another disadvantage of Cu is that it exhibits poor electromigration resistance. Accordingly, there exists a need for semiconductor methodology enabling the formation of reliable Cu or Cu alloy interconnection patterns with improved electromigration resistance. There exist a particular need for simplified methodology enabling the formation of electromigration resistant Cu interconnects in high speed integrated circuits having submicron design features.

### SUMMARY OF THE INVENTION

It is an object an embodiment of the present invention to provide a structure and a method for fabricating a connection comprised of copper having a compound cap layer.

An example embodiment of the present invention provides a structure and method of manufacturing a copper connecting which is characterized as follows. A copper interconnect is formed over a structure. A tin layer is formed on the copper interconnect. The tin layer and copper interconnect are annealed to form a Cu—Sn compound cap layer on the copper interconnect.

In another embodiment a dielectric cap layer is formed on the Cu—Sn compound cap layer.

In yet another example embodiment, the cap layer is comprised of nickel.

The above advantages and features are of representative embodiments only, and are not exhaustive and/or exclusive. They are presented only to assist in understanding the invention. It should be understood that they are not representative of all the inventions defined by the claims, to be considered limitations on the invention as defined by the claims, or limitations on equivalents to the claims. For instance, some of these advantages may be mutually contradictory, in that they cannot be simultaneously present in a single embodiment. Similarly, some advantages are applicable to one aspect of the invention, and inapplicable to others. Furthermore, certain aspects of the claimed invention have not been discussed herein. However, no inference should be drawn regarding those discussed herein relative to those not discussed herein other than for purposes of space and reducing repetition. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

The features and advantages of a semiconductor device according to the present invention and further details of a process of fabricating such a semiconductor device in accordance with the present invention will be more clearly understood from the following description taken in conjunction with the accompanying drawings in which like reference numerals designate similar or corresponding elements, regions and portions and in which:

FIGS. 1A, 1B, 1C and 1D are cross sectional views for illustrating a example embodiment for forming a Cu—Sn compound cap layer using a selective Sn process according to a first example embodiment of the present invention.

FIGS. 1A-1, 1B-1, 1C-1, 1C-2 and 1D-1 are close up cross sectional views of the top corners of the interconnects shown in FIGS. 1A, 1B, 1C and 1D according to a first example embodiment of the present invention.

FIGS. 2A, 2B, 2C, 2D and 3E are cross sectional views for illustrating an example embodiment for forming a Cu—Sn compound cap layer using a blanket Sn process according to a second example embodiment of the present invention.

FIGS. 3A, 3B, 3C, and 3D are cross sectional views for illustrating a example embodiment for forming a Ni cap layer using a selective Ni process according to a third example embodiment of the present invention.

FIG. 4 shows an interconnect with a compound cap layer thereover according to a example embodiment of the present invention.

FIG. 5A, shows a Sn—Cu compound capping layer used as a cap layer in a UMB metallization in flip-chip technology according to an example embodiment of the present invention.

FIG. 5B, shows a Sn—Cu compound capping layer used as a conductive pad surface metallization in a printed circuit board (PCB) according to an example embodiment of the present invention.

FIG. 6 shows a close up cross sectional view of a copper interconnect 604 having a chemical-mechanical polish (CMP) created recesses or so called “tiger teeth” in the top surface of the interconnect.

### DETAILED DESCRIPTION OF THE PREFERRED EMBODIMENTS

### I. Introduction

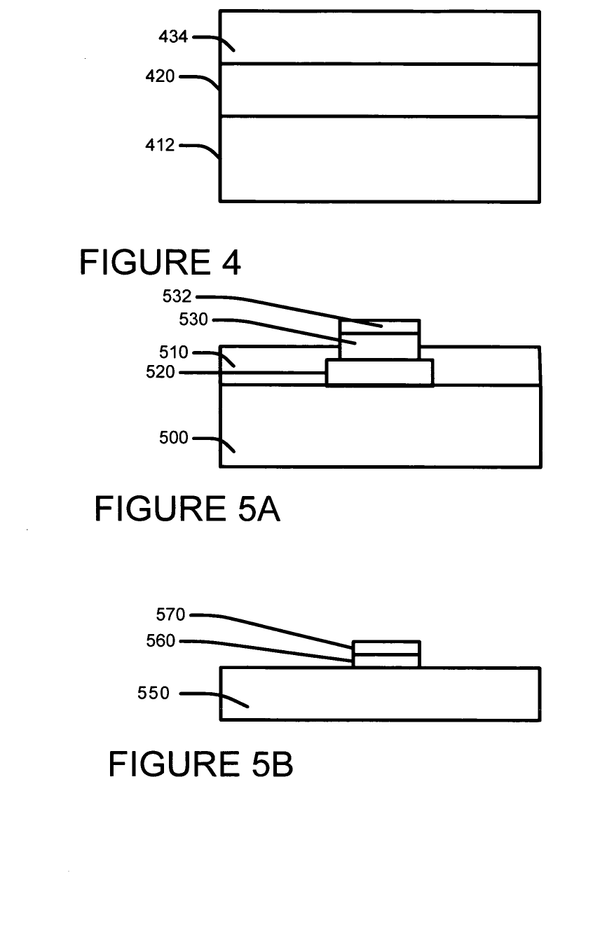

An example embodiment of the invention is an interconnect structure comprising: an interconnect and a compound metal cap layer. Referring to FIG. 4, an interconnect 412 has a compound cap layer 420 thereover. A dielectric cap layer 434 is on the compound metal cap layer 420. The interconnect 412 is preferably comprised of copper. The compound cap layer 420 is preferably comprised of a copper-metal (Cu-Me) compound and is more preferably comprised of a Cu—Sn compound or Ni.

A compound is a distinct substance formed by chemical union of two or more ingredients in definite proportion.

The embodiment's compound cap layer provides many benefits. The compound cap layer can provide a barrier capping effect to the Cu to minimize the out-diffusion of Cu and therefore improve the EM performance of Cu. The conductivity of such compound as Cu₃Sn is about 8.9 micro-ohm-cm.

The compound cap layer has excellent adhesion to dielectric cap layers, especially SiN and SiC dielectric cap layers.

Note, that the terms such first interconnect/layer, second interconnect/layer, are relative terms and can refer to any level structure.

In a first example embodiment, the Cu—Sn compound cap layer is formed using a selective Sn plating.

In a second example embodiment, the Cu—Sn compound cap layer is formed using a Sn sputter.

In a third example embodiment, a Ni cap layer is formed on the Cu interconnect preferably using a selective Ni plating,

### II. First Embodiment

Selective Sn Plating For Compound Metal Cap Layer

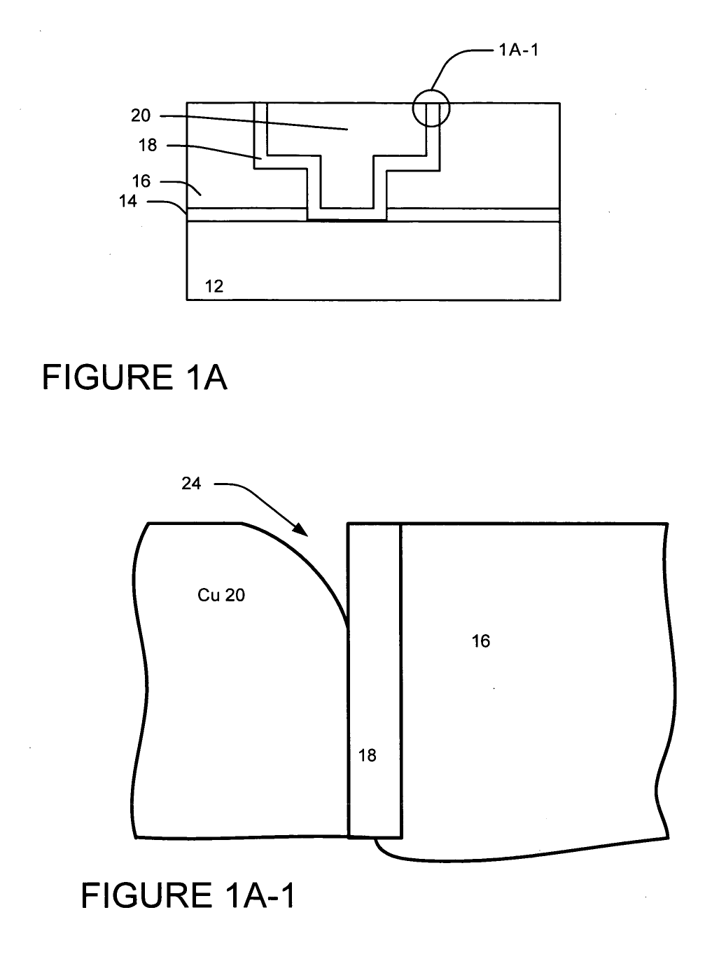

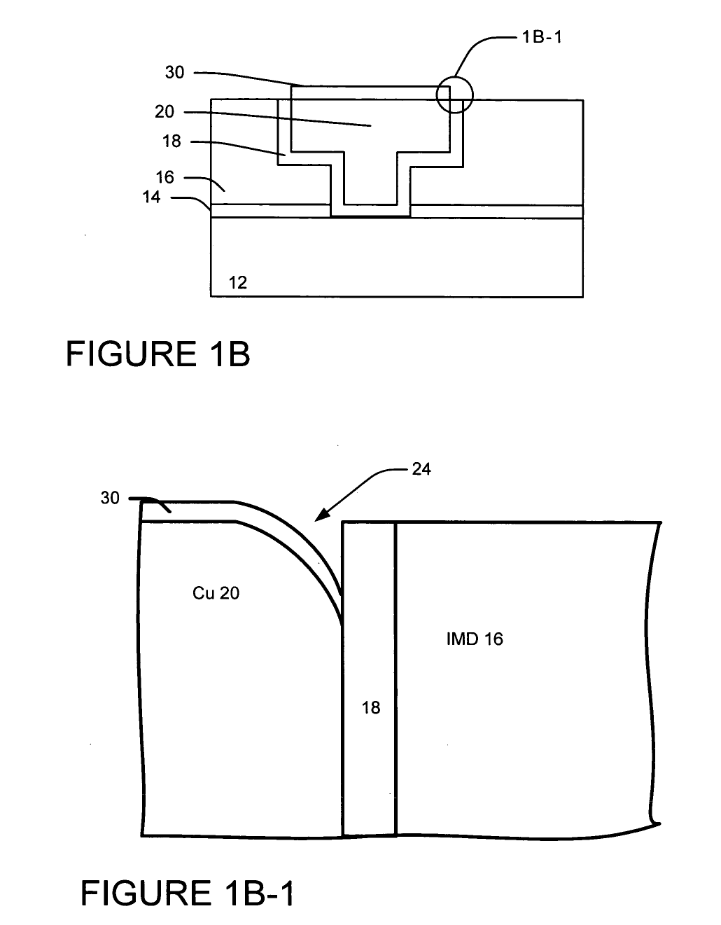

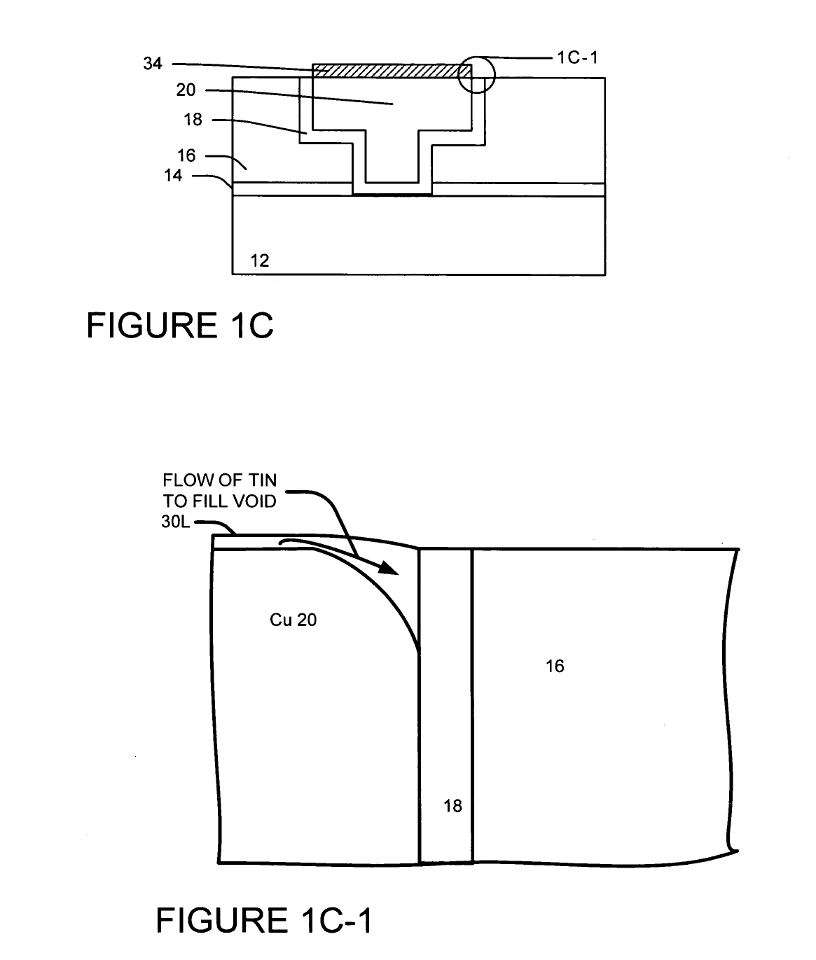

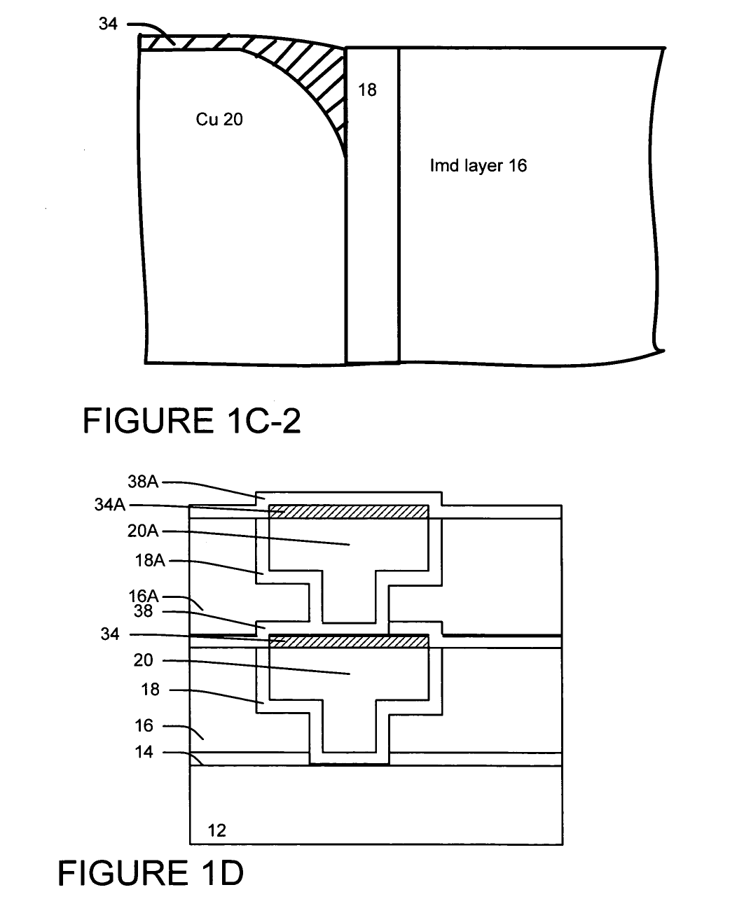

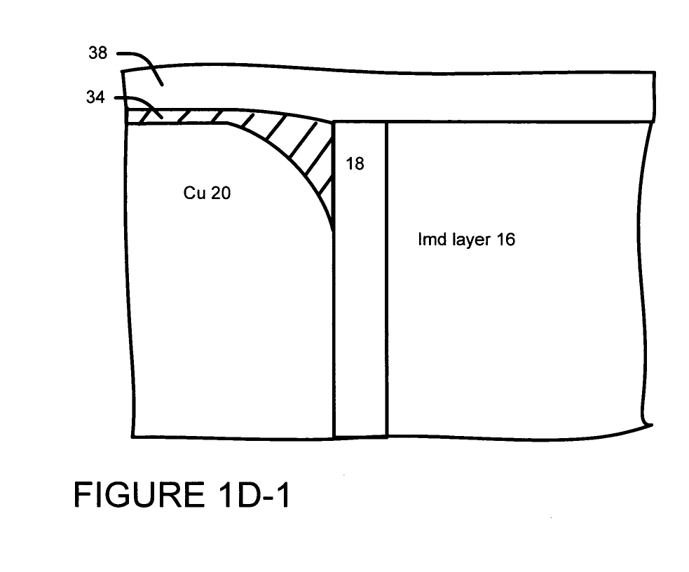

In a first embodiment shown in FIGS. 1A to 1D, a selective Sn plating process forms the tin layer that is annealed to form the Cu—Sn compound cap layer over the Cu interconnect.

Provide Interconnect

Referring FIG. 1A, we form a lower capping layer 14 (e.g., lower dielectric capping layer) over a semiconductor structure 12. The semiconductor structure 12 can comprise a substrate with dielectric layers and conductive layers thereover. The dielectric layers can be inter metal dielectric (IMD) layers. The substrate can be a silicon wafer. The upper surface of the semiconductor structure is preferably comprised of a dielectric layer and a lower level interconnect or contact (not shown).

The lower capping layer 14 (e.g., dielectric capping layer) is preferably comprised of SiCO, SiCN, SiC or SiN or combinations thereof and is most preferably comprised of SiC or SiN. The barrier layer preferably has a thickness between 450 Å and 550 Å.

Next we form an inter metal dielectric (IMD) layer 16 over the semiconductor structure 12. The IMD layer is preferably comprised of oxide or low K or Ultra low K material and can be formed by a chemical vapor deposition process. The inter metal dielectric layer preferably has a thickness between 6000 Å and 30,000 Å.

We form an interconnect opening in the inter metal dielectric layer 16. The interconnect opening is preferably a dual damascene shaped opening. The interconnect opening can be a single damascenes opening for the first level metal.

We then form a barrier layer 18 on the IMD layer 16 in at least the interconnect opening. The barrier layer 18 is preferably comprised of a metal barrier layer, Ta, TaN, TiW or W and preferably has a thickness between 100 and 500 Å.

Still referring to FIG. 1A, we form a copper interconnect 20 in the interconnect opening. The copper interconnect is preferably comprised of copper with a concentration between 99 and 99.5% Cu. Note, normally there will be a certain amount of residues from the plating bath used.

The copper interconnect is preferably formed using a sputter or plating process and most preferably formed using a electroplating process.

Next, preferably we perform a chemical-mechanical polish (CMP) process to planarized the copper interconnect to a level about even with the top surface of the IMD layer 16.

FIG. 1A-1 shows a close up of the section shown in FIG. 1A. The copper interconnect 20 is shown after a chemical-mechanical polish (CMP) step that can create the potentially harmful “tiger teeth” void 24 in the interconnect 20 around the edge near the barrier layer 18.

Form a Tin (Sn) Layer on the Copper Interconnect

Referring to FIG. 1B, we form a tin (Sn) layer 30 on the copper interconnect 20. The tin (Sn) layer 30 can be formed by selectively plating Sn on the copper interconnect 20.

The tin layer is preferably comprised of Sn with a concentration between 99 and 99.5% Sn and is most preferably essentially pure Sn. Normally the Sn from the plating process contains some small amount of impurities from the plating bath.

FIG. 1B-1 shows the tin layer 30 selectively formed on the interconnect 20. The tin layer 30 may partially fill up or totally fill up the void 24.

Thermally Anneal the Tin Layer to Form a Cu—Sn Compound Cap Layer on the Copper Interconnect

As shown in FIG. 1C, we thermally annealing the tin layer 30 to form a (Cu₃Sn) Cu—Sn compound cap layer 34 on the copper interconnect 20.

The most common Cu—Sn compound phases are Cu₃Sn and Cu₆Sn₅. The exact phase will depend on the compositions and the heat treatment temperature. A preferred embodiment uses Cu₃Sn because Cu₃Sn is more stable than Cu₆Sn₅. Cu₆Sn₅ can transform into Cu₃Sn during a solid state anneal.

A compound is a distinct substance formed by chemical union of two or more ingredients in definite proportion.

The Cu₃Sn is an intermetalic compound with a crystalline structure different from its constitutes (Cu or Sn)). The Cu₃Sn has a very specific ratio of Cu to Sn.

The embodiment's Cu—Sn compound cap layer 34 is self aligned over the Cu interconnect 20 through liquid-solid reaction of between the Sn(l) and Cu (s).

The Cu—Sn compound cap layer 34 is preferably comprised of Cuₓ Sn_{y}, such as Cu₃Sn and Cu₆Sn₅.

The thermal anneal is performed at a temperature between 240 and 320 degrees C. and more preferably between 260 and 300 degrees C.; and for a time between 1 minute and 10 minutes; in an inert gas atmosphere preferably of N₂ or Ar or N₂+H₂. The anneal temperature can be constant or a profile as long as a uniform temperature across the wafer and no significant stress built up occurs across the wafer.

A liquid-solid reaction occurs between copper interconnect and Sn layer to form the (Cu₃Sn ) Cu—Sn compound cap layer.

At temperatures above 240 degrees C., the Sn layer will change to liquid phase/form. This liquid Sn is very reactive with solid Cu and can form real compound Cu₃Sn if control the temperature and time properly.

The anneal changes Sn solid into Sn liquid. Then the liquid Sn reacts with the solid Cu to form a Cu—Sn compound. The anneal is preferably not primarily a solid Sn-Solid Cu diffusion process.

Referring to FIG. 1C-1, during the first part of the anneal process, at least a portion of the tin layer 30 changes to liquid phase (e.g., liquid phase tin 30L). The liquid tin layer 30L can flow into the void 24 to fill the void 24. The surface tension and high mobility of the liquid tin layer enable the flow.

Liquid Sn and solid Cu will react during temperature holding above the liquification temperature of Sn. It is thought that initially, Cu will dissolve in the Sn(l) due to the solubility of Cu and Sn(l). Localized super saturation will always exist and Cu₃Sn will precipitate at the Sn(L)/Cu(s) interface with the proper control of the temperature and time. A uniform layer of CuSn can be formed on top of a Cu line.

The continuous Cu—Sn (Cu₃Sn) compound cap layer forms a strong and hard diffusion barrier and confinement layer.

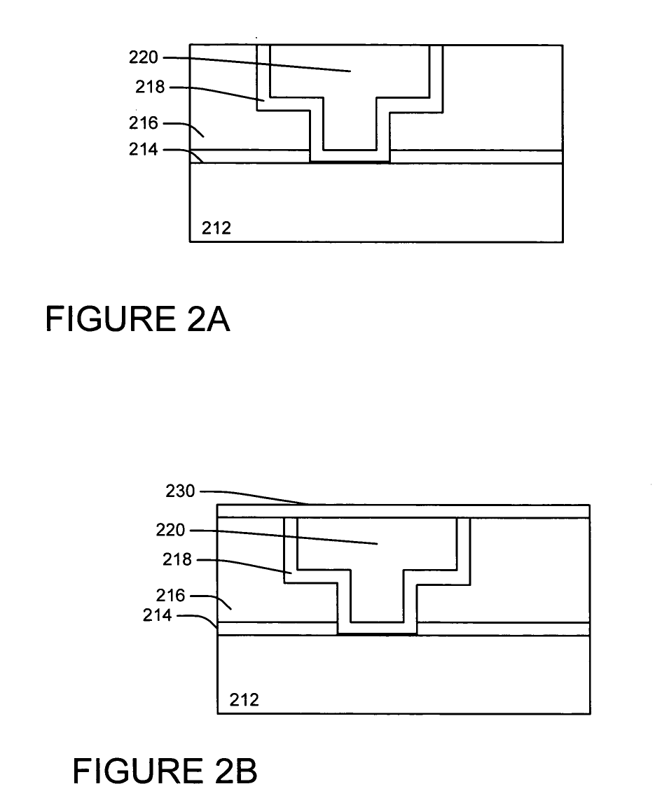

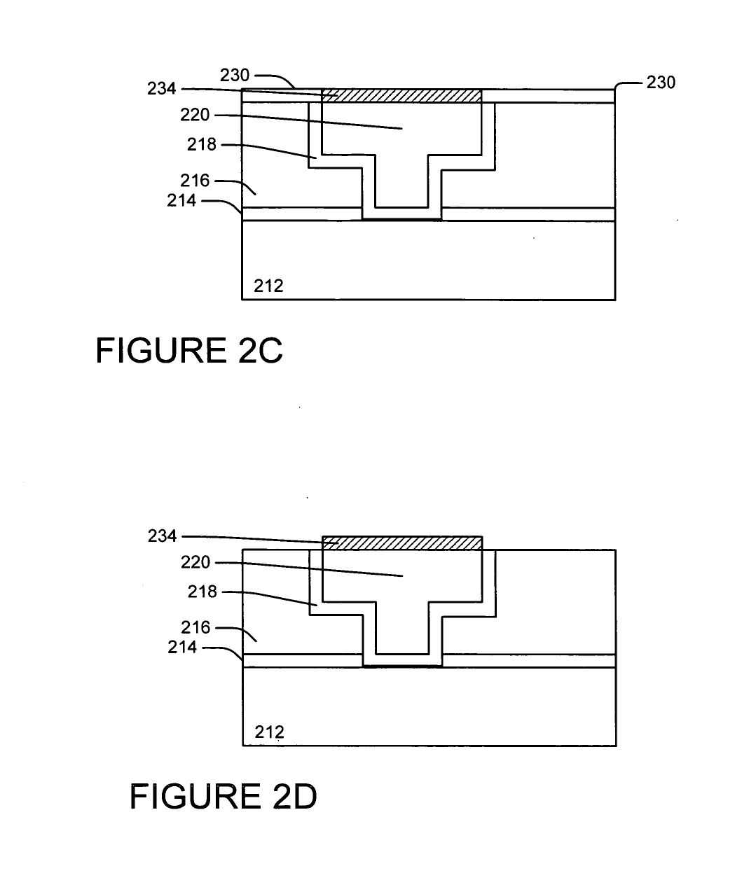

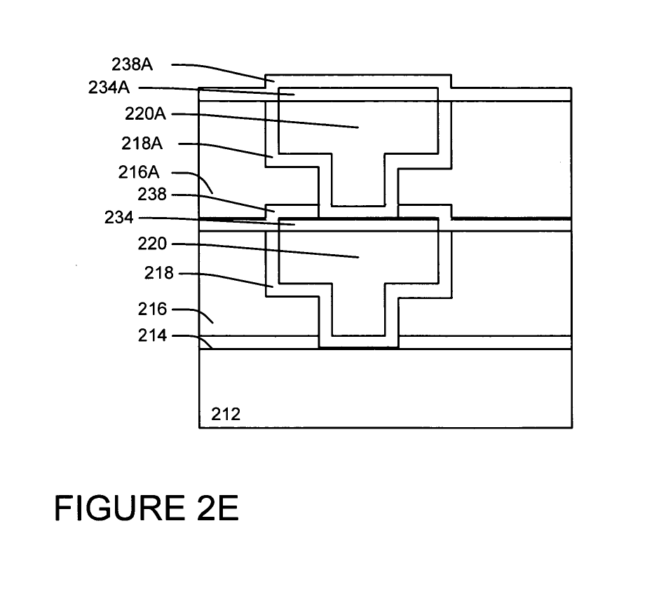

Referring to FIG. 1C-2, during a second part of the anneal process, at least a portion of the liquid phase tin 30L reacts to form the Cu—Sn compound cap layer 34. The Cu—Sn compound cap layer 34 can block the out-diffusion of Cu form this void/weak area.

Form a Dielectric Cap Layer on the Cu—Sn Compound Cap Layer and the IMD Layer

Referring to FIG. 1D, we preferably form a dielectric cap layer 38 on the Cu—Sn compound cap layer 34 and the IMD layer 16. The dielectric cap layer 38 can be comprised of SiN or SiC, nitrogen doped SiC, or oxygen doped SiC or combinations thereof and is preferably comprised of SiN or SiC.

The dielectric cap layer 38 preferably has a thickness of between 450 and 550 Å.

FIG. 1D-1 shows a close up cross sectional view of the Cu—Sn compound cap layer 34 and overlaying first dielectric cap layer 28. The dielectric cap layer 38 will follow the “flat” contour of the tiger teeth region over the Cu—Sn compound cap layer 34. The embodiments' Cu—Sn compound cap layer 34 and dielectric cap layer 38 significantly reduce the stress in the void area.

FIG. 1D also shows another IMD layer and interconnect formed over the first interconnect. FIG. 1D shows (i.e., next level) second IMD layer 16A, (i.e., next level) second barrier layer 18A, (i.e., next level) second interconnect 20A, (i.e., next level) second Cu—Sn compound layer 34A and (i.e., next level) second dielectric cap layer 38A. Corresponding elements can be formed as described above. The terms first and second, etc. are relative terms. The embodiment can be implemented at any level.

### III. Second Embodiment

Sn Sputtering

In the second embodiment, a Sn sputter step forms the tin layer that is reacted to form the Cu—Sn compound cap layer over the Cu interconnect. The corresponding elements can be formed as described above in the first embodiment.

Referring to FIG. 2A, a copper interconnect 220 is formed over a semiconductor structure 212. The semiconductor structure 212 can comprise a substrate with dielectric layers and conductive layers thereover. The dielectric layers can be inter metal dielectric (IMD) layers. The substrate can be a silicon wafer.

A lower capping layer 214 is formed over a semiconductor structure 212.

Next we form an inter metal dielectric (IMD) layer 216 over the semiconductor structure 212.

We form an interconnect opening in the IMD layer 216 and the lower capping layer 214. The interconnect can be any shape such as a single damascene opening or dual damascene opening. The interconnect is preferably a dual damascene shaped opening.

We then form a barrier layer 218 on the IMD layer 216 in at least the interconnect opening.

Still referring to FIG. 2A, we form a copper interconnect 220 in the interconnect opening.

Next we perform a chemical-mechanical polish (CMP) process to planarized the copper interconnect to a level about even with the top surface of the IMD layer 216. The chemical-mechanical polish (CMP) process can produce recesses/voids (tiger teeth voids) in the interconnect 220 as described herein.

Sputtering Sn on the Copper Interconnect and the IMD Layer

As shown in FIG. 2B, we form a tin (Sn) layer 230 on the copper interconnect 220. The tin layer 230 is formed by sputtering Sn on the copper interconnect 220 and the IMD layer 216.

The tin layer is preferably comprised of Sn with a concentration between 99 and 99.9% Sn.

Anneal the Tin Layer to Form a Cu—Sn Compound Cap Layer

Referring to FIG. 2C, we thermally anneal the tin layer to form a Cu—Sn compound cap layer 234 (e.g., Cu₃Sn) on the copper interconnect 20. The Sn layer over the IMD layer 216 remains as single element Sn.

The thermal anneal is preferably performed as described above. The anneal changes the Sn to liquid phase where the liquid Sn can flow to fill any voids/recesses on the interconnect.

Removing Any Unreacted Tin Layer Over the Dielectric Layer

Referring to FIG. 2D, we remove any unreacted tin layer 230 especially over the dielectric layer 216.

The remaining unreacted Sn preferably can be removed by wet clean using either diluted HCl (for example, 1 to 3% by volume HCl in water) or other diluted acidic chemicals solutions. While due to the high resistance of Cu₃Sn compounds to the above chemicals, no Cu3Sn will be affected. Since all the Cu surfaces have been changed into Cu3Sn surface, Cu will not affected too.

Form a Dielectric Cap Layer on the Cu—Sn Compound Cap Layer and the IMD Layer

Referring to FIG. 2E, we preferably form a dielectric cap layer 238 on the Cu—Sn compound cap layer 234 and the IMD layer 216.

FIG. 2E shows another inter metal dielectric layer and interconnect formed over the (i.e., previous level) first interconnect. FIG. 2E shows (next level) second IMD layer 216A, barrier layer 218A, second interconnect 220A, Cu—Sn compound layer 234A and second dielectric cap layer 238A. Corresponding elements can be formed as described above.

### IV. Third Example Embodiment

Ni Metal Cap Layer

In the third embodiment, preferably a selective Ni plating step forms the Ni layer that is reacted with Cu to form the Ni cap layer over the Cu interconnect. The corresponding elements can be formed as described above.

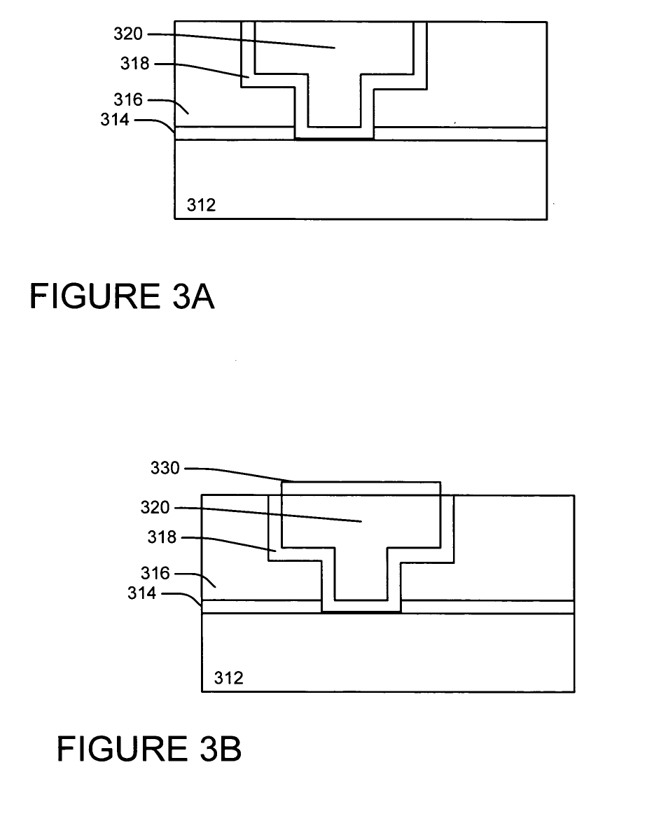

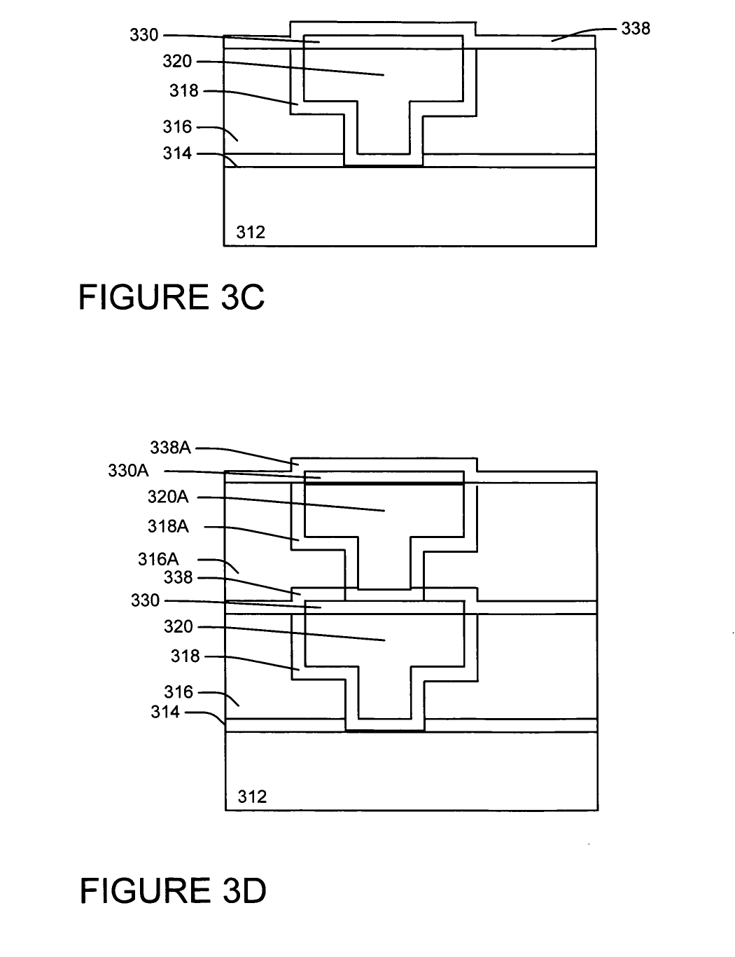

Referring to FIG. 3A, a copper interconnect 320 is formed over a semiconductor structure 312. The semiconductor structure 312 can comprise a substrate with dielectric layers and conductive layers thereover. The dielectric layers can be inter metal dielectric (IMD) layers. The substrate can be a silicon wafer.

A lower dielectric capping layer 314 is formed over a semiconductor structure 312.

Next we form an IMD layer 316 over the semiconductor structure 312.

We form an interconnect opening in the IMD layer 316 and the lower cap layer. The interconnect is preferably a dual damascene shaped opening.

We then form a barrier layer 318 on the IMD layer 316 in at least the interconnect opening.

Still referring to FIG. 3A, we form a copper interconnect 320 in the interconnect opening.

Next we perform a chemical-mechanical polish (CMP) process to planarized the copper interconnect to a level about even with the top surface of the IMD layer 316. The chemical-mechanical polish (CMP) can create recesses in the interconnect as described herein.

Form a Nickel (Ni) Layer on the Copper Interconnect

Referring to FIG. 3B, we form a nickel (Ni) layer 330 on the copper interconnect 320.

The nickel layer 330 is preferably formed by selectively plating Ni on the copper interconnect 320. The nickel layer can be formed by other processes such as sputtering. However, it may be difficult to remove the Ni layer from over the non-interconnect areas.

The nickel layer preferably comprised of essentially pure Ni.

The continuous Ni cap layer forms a strong and hard diffusion barrier and confinement layer.

Forming a Dielectric Cap Layer 338 on the Ni Cap Layer

Referring to FIG. 3C, we preferably form a dielectric cap layer 338 on the Ni cap layer 330 and the IMD layer 316.

FIG. 3D shows another IMD layer and interconnect formed over the first interconnect. FIG. 3D shows second IMD layer 316A, barrier layer 318A, second interconnect 320A, second Ni compound layer 330 and second dielectric cap layer 338A. Corresponding elements can be formed as described above.

### V. Some Benefits of Some Example Embodiments

The embodiment's “Conductive Compound Capping Layer” Cu_{X}M_{Y} can be Cu—Sn compounds, such as Cu₃Sn, etc.

Cu (Sn) alloys with different Sn contents possessed higher EM performances although the interconnect resistance increased. This implies that the EM performance for the “Conductive Compound Capping Layer” will be better than Cu itself.

Same example embodiments can have the some following advantages:
1. This compound cap layer can provide a barrier capping effect to the Cu to minimize the out-diffusion of Cu and therefore improve the EM performance of Cu. The conductivity of such compound as Cu₃Sn is ˜8.9 micro.ohm.cm.
2. The compound cap layer such as Cu₃Sn possesses much higher hardness (340 Kg/mm2) and modulus (110 GPa) compared to Cu. Therefore it can provide a confinement effect to the Cu to enhanced the EM performance.
3. The compounds, such as Cu₃Sn, has good adhesion with Cu and therefore reduce delamination problems for such cap/Cu interface
4. Unlike Cu, the compounds cap materials are very resistant to the oxidation and therefore prevent the direct exposure and oxidation of Cu surface.
5. The Sn—Cu compounds can have a irregular shape (e.g., scallop shape microscopically). The irregular surface of the Sn—Cu compounds will provide good adhesion with the SiC or SiN based capping layer. In addition, since Sn will deposit to the surface of Cu after CMP, it will fill-up the recessed areas on the edge of the metal lines (so-called “tiger teeth”) due to CMP. Normally such “tiger teeth” will leave a sharp tip of SiC or SiN based capping which potentially will induce higher stress level there.

### VI. Other Embodiments

The embodiment's Cu—Sn compound capping layers can also be used as a cap layer in a UMB in flip-chip technology. As shown in FIG. 5A, an example semiconductor structure 500 is shown with a copper bonding pad 520, a UMB (under bump metallization) 530, cap layer 532 and passivation layer 510. A cap layer 532 is preferably comprised of the embodiment's Cu—Si compound cap. The UBM layer can be comprised of several metal layers. A bump is formed over the capping layer 532.

Also another option, the embodiment's Sn—Cu capping layers can be used in the conductive pad surface metallization in PCB's. As shown in FIG. 5B, a printed circuit board (PCB) 550 has a conduction pad 560 with a conductive pad surface metallization comprised of the embodiments' Cu—Sn compound cap layer 570.

### VII. CMP of Interconnect Can Create a Recess at the Top Corners of the Interconnect

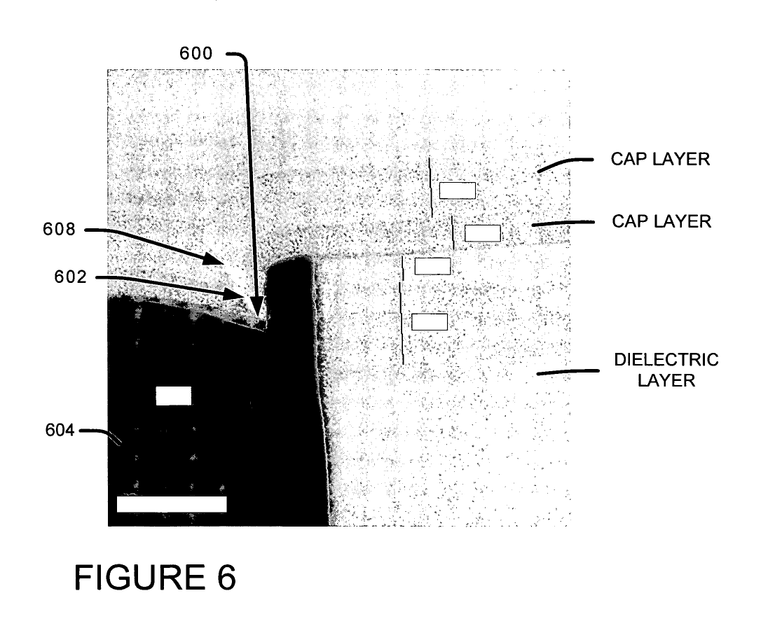

Referring to FIG. 6, the chemical-mechanical polish (CMP) of the copper interconnect can create recesses or tiger teeth at the top edges of the interconnect and the IMD layer.

FIG. 6 shows a close up cross sectional view of a copper interconnect 604 in dielectric layers. The chemical-mechanical polish (CMP) created recesses 600 or so called “tiger teeth” in the top surface of the interconnect 604. The dielectric capping layers have problems such as (1) discontinuity 602 of the dielectric cap layers, and (2) higher mechanical stress in the overlaying dielectric cap layers at the corners 608.

The embodiment's can fill the recesses or tiger teeth with metal or compound cap layer to alleviate the recess problem.

Although this invention has been described relative to specific insulating materials, conductive materials and apparatuses for depositing and etching these materials, it is not limited to the specific materials or apparatuses but only to their specific characteristics, such as conformal and nonconformal, and capabilities, such as depositing and etching, and other materials and apparatus can be substituted as is well understood by those skilled in the microelectronics arts after appreciating the present invention

Given the variety of embodiments of the present invention just described, the above description and illustrations show not be taken as limiting the scope of the present invention defined by the claims.

While the invention has been particularly shown and described with reference to the preferred embodiments thereof, it will be understood by those skilled in the art that various changes in form and details may be made without departing from the spirit and scope of the invention. It is intended to cover various modifications and similar arrangements and procedures, and the scope of the appended claims therefore should be accorded the broadest interpretation so as to encompass all such modifications and similar arrangements and procedures.

1. A method of forming a compound capping layer over a copper interconnect; comprising the steps of:
a) forming a copper interconnect over a structure;
b) forming a tin layer on said copper interconnect;
c) thermally annealing said tin layer and copper interconnect to form a Cu—Sn compound cap layer on said copper interconnect.

2. The method of claim 1 which further includes:
forming a dielectric cap layer on said Cu—Sn compound cap layer and said inter metal dielectric layer.

3. The method of claim 1 wherein said Cu—Sn compound cap layer is comprised of Cu₃Sn or Cu₅Sn₆.

4. The method of claim 1 wherein said copper interconnect is a bond pad, said Cu—Sn compound cap layer is a under bump metal, and the method further includes:
forming a solder bump over said Cu—Sn compound cap layer.

5. The method of claim 1 wherein said structure is a printed circuit board, said copper interconnect is a printed circuit board pad, said Cu—Sn compound cap layer is a conductive pad surface metallization.

6. The method of claim 1 wherein the thermal anneal of said tin layer and said copper interconnect cause the tin layer to convert to a liquid phase tin, the liquid phase tin reacts with the solid phase copper interconnect to form the Cu—Sn compound cap layer.

7. A method of forming a compound capping layer over a copper interconnect; comprising the steps of:
a) forming an inter metal dielectric layer over said semiconductor structure;
b) forming an interconnect opening in said inter metal dielectric layer;
c) forming a copper interconnect in said interconnect opening;
d) forming a tin layer on said copper interconnect;
e) thermally annealing said tin layer to form a Cu—Sn compound cap layer on said copper interconnect.

8. The method of claim 7 which further includes: forming a dielectric cap layer on said Cu—Sn compound cap layer and said inter metal dielectric layer.

9. The method of claim 7 which further includes: forming a dielectric cap layer on said Cu—Sn compound cap layer and said inter metal dielectric layer; said dielectric cap layer comprised of SiN or SiC and has a thickness of between 450 and 550 Å.

10. The method of claim 7 wherein said Cu—Sn compound cap layer is comprised of Cu₃Sn or Cu₅Sn₆.

11. The method of claim 7 wherein said copper interconnect formed by forming a copper layer in said interconnect opening and planarizing said copper layer; the planarization creating a recess on the top edges of said copper interconnect;
and said Cu—Sn compound layer fills said recesses in said copper interconnect.

12. The method of claim 7 which further includes: before step (a):
forming a capping layer over a semiconductor structure; said capping layer is comprised of a material selected from the group consisting of SiCo, SiCN, SiC, SiN and combinations thereof.

13. The method of claim 7 which further includes before the step of forming the copper interconnect:
forming a barrier layer in said interconnect opening on said inter metal dielectric layer.

14. The method of claim 7 wherein said copper interconnect is formed by forming a copper layer in said interconnect opening and planarizing said copper layer using a chemical-mechanical polish process; the planarization creating a recess on the top edges of said copper interconnect.

15. The method of claim 7 wherein said tin layer is formed by selectively plating Sn on said copper interconnect.

16. The method of claim 7 wherein said tin layer is formed by sputtering Sn on said copper interconnect and said inter metal dielectric layer; and after step (e) removing any remaining tin layer.

17. The method of claim 7 wherein the thermal anneal is performed at a temperature between 240 and 320 degrees C. and a liquid-solid reaction occurs between copper interconnect and Sn layer to form said Cu—Sn compound cap layer.

18. The method of claim 7 wherein the thermal anneal is performed at a temperature between 260 and 300 degrees C.; and for a time between 1 and 10 minutes; and a liquid-solid reaction occurs between Copper interconnect and Sn layer to form said Cu—Sn compound cap layer.

19. The method of claim 7 wherein said Cu—Sn compound cap layer is comprised of Cu₃Sn or Cu₅Sn₆.

20. A method of forming a Ni cap layer over a copper interconnect; comprising the steps of:
a) forming an inter metal dielectric layer over said semiconductor structure;
b) forming an interconnect opening in said inter metal dielectric layer;
c) forming a barrier layer on said inter metal dielectric layer in said interconnect opening;
d) forming a copper interconnect in said interconnect opening; and
e) forming a nickel layer selectively on said copper interconnect to form a Ni cap layer.

21. The method of claim 20 which further includes: forming a dielectric cap layer on said Ni cap layer and said inter metal dielectric layer.

22. The method of claim 20 which further includes: forming a dielectric cap layer on said Ni cap layer and said inter metal dielectric layer.

23. The method of claim 20 wherein said copper interconnect formed by forming a copper layer in said interconnect opening and planarizing said copper layer; the planarization creating a recess on the top edges of said copper interconnect.

24. The method of claim 20 wherein said nickel layer is formed by selectively plating Ni on said copper interconnect to form said Ni cap layer.

25. A copper interconnect for an electronic device; comprising:
an inter metal dielectric layer over a semiconductor structure;
an interconnect opening in said inter metal dielectric layer;
a copper interconnect in said interconnect opening;
a copper-metal compound cap layer on said copper interconnect.

26. The copper interconnect of claim 25 that further comprises: a dielectric cap layer on said copper-metal compound cap layer and said inter metal dielectric layer.

27. The copper interconnect of claim 25 that further comprises: a recess on the top edges of said copper interconnect;
said copper-metal compound layer fills said recesses in said copper interconnect.

28. The copper interconnect of claim 25 that further comprises:
a capping layer on a semiconductor structure and under said inter metal dielectric layer; said capping layer is comprised of SiCO, SiCN, SiC or SiN has a thickness of between 450 and 550 Å.

29. The copper interconnect of claim 25 that further comprises: said inter metal dielectric layer is comprise of oxide.

30. The copper interconnect of claim 25 that further comprises: said copper-metal compound cap layer is comprised of Cu₃Sn or Cu₅Sn₆.

31. The copper interconnect of claim 25 that further comprises: said copper-metal compound cap layer is comprised of Cu₃Sn said copper-metal compound cap layer covers only the entire top surface of said copper interconnect.

32. The copper interconnect of claim 25 wherein said semiconductor structure comprises a silicon chip.

33. The copper interconnect of claim 25 wherein said copper interconnect is a copper bonding pad and said copper-metal compound cap layer is a under bump metallization.

34. The copper interconnect of claim 25 wherein semiconductor structure is a printed circuit board;
said copper interconnect is a copper pad and said copper-metal compound cap layer is a conductive pad surface metallization.
